(19) United States
(12) Patent Application Publication
(10) Pub. No.: US 2016/0211333 A1
(43) Pub. Date: Jul. 21, 2016

(54) SILICON CARBIDE SEMICONDUCTOR DEVICE AND METHOD OF MANUFACTURING THE SAME

(71) Applicant: SUMITOMO ELECTRIC INDUSTRIES, LTD., Osaka-shi (JP)

(72) Inventor: Takeyoshi Masuda, Osaka-shi (JP)

(21) Appl. No.: 14/916,847

(22) PCT Filed: Jul. 23, 2014
(86) PCT No.: PCT/JP2014/069405

§ 371 Date: Mar. 4, 2016

(30) Foreign Application Priority Data
Sep. 6, 2013 (JP) 2013-185032

(51) Int. Cl. H01L 29/16; H01L 29/51; H01L 29/78; H01L 21/04; H01L 29/66; H01L 29/49; H01L 21/02

(52) U.S. Cl. CPC H01L 29/1608; H01L 29/4916; H01L 29/51; H01L 21/02164; H01L 21/049; H01L 21/0485; H01L 29/66068; H01L 29/7802

(57) ABSTRACT

A SiC semiconductor device includes a SiC substrate, a gate insulating film formed on a surface of the SiC substrate and made of SiO₂, and a gate electrode formed on the gate insulating film. A maximum value of a nitrogen concentration in a region within 10 nm from an interface between the SiC substrate and the gate insulating film is greater than or equal to 3×10¹⁹ cm⁻³. A maximum value of a nitrogen concentration in a region within 10 nm from an interface between the gate insulating film and the gate electrode is less than or equal to 1×10²⁰ cm⁻³.

### TECHNICAL FIELD

The present invention relates to silicon carbide semiconductor devices and methods of manufacturing the same, and more specifically to a silicon carbide semiconductor device having improved channel mobility as well as a high threshold voltage and a method of manufacturing the same.

### BACKGROUND ART

In recent years, silicon carbide has been increasingly employed as a material constituting a semiconductor device in order to allow for a higher breakdown voltage, lower loss and the like of the semiconductor device. Silicon carbide is a wide band gap semiconductor having a band gap wider than that of silicon which has been conventionally and widely used as a material constituting a semiconductor device. By employing the silicon carbide as a material constituting a semiconductor device, therefore, a higher breakdown voltage, lower on-resistance and the like of the semiconductor device can be achieved. A semiconductor device made of silicon carbide is also advantageous in that performance degradation is small when used in a high-temperature environment as compared to a semiconductor device made of silicon.

Examples of a semiconductor device containing silicon carbide as a constituent material include a MOSFET (Metal Oxide Semiconductor Field Effect Transistor). A MOSFET is a semiconductor device in which a current is allowed or not allowed to pass by controlling whether or not an inversion layer is formed in a channel region with a prescribed threshold voltage being defined as a boundary. Japanese Patent Laying-Open No. 2011-82454 (hereinafter referred to as PTD 1), for example, discloses a silicon carbide semiconductor device in which channel resistance is suppressed and a threshold voltage is stable without temporal variation.

### CITATION LIST

### Patent Document

PTD 1: Japanese Patent Laying-Open No. 2011-82454

### SUMMARY OF INVENTION

### Technical Problem

In the silicon carbide semiconductor device described above, it is required, in addition to suppressing the channel resistance and threshold voltage variation, to increase an absolute value of the threshold voltage.

The present invention has been made in view of the aforementioned problem, and an object of the present invention is to provide a silicon carbide semiconductor device having improved channel mobility as well as a high threshold voltage and a method of manufacturing the same.

### Solution to Problem

A silicon carbide semiconductor device according to the present invention includes a silicon carbide substrate, a gate insulating film formed on a surface of the silicon carbide substrate and made of silicon oxide, and a gate electrode formed on the gate insulating film. In the silicon carbide semiconductor device described above, a maximum value of a nitrogen concentration in a region within 10 nm from an interface between the silicon carbide substrate and the gate insulating film is greater than or equal to 3×10¹⁹ cm⁻³. In the silicon carbide semiconductor device described above, a maximum value of a nitrogen concentration in a region within 10 nm from an interface between the gate insulating film and the gate electrode is less than or equal to 1×10²⁰ cm⁻³cm.

A method of manufacturing a silicon carbide semiconductor device according to the present invention includes the steps of preparing a silicon carbide substrate, forming a gate insulating film made of silicon oxide on a surface of the silicon carbide substrate, heating the silicon carbide substrate having the gate insulating film formed thereon at a temperature greater than or equal to 1100° C. in an atmosphere including nitrogen, and after the step of heating the silicon carbide substrate, forming a gate electrode on the gate insulating film. In the method of manufacturing a silicon carbide semiconductor device described above, after the step of forming a gate electrode, the silicon carbide substrate is not heated at a temperature greater than or equal to 900° C. in an atmosphere including greater than or equal to 10% nitrogen.

### Advantageous Effects of Invention

According to the silicon carbide semiconductor device in accordance with the present invention, a silicon carbide semiconductor device having improved channel mobility as well as a high threshold voltage can be provided. According to the method of manufacturing a silicon carbide semiconductor device in accordance with the present invention, a silicon carbide semiconductor device having improved channel mobility as well as a high threshold voltage can be manufactured.

### BRIEF DESCRIPTION OF DRAWINGS

FIG. 1 is a schematic sectional view showing a structure of a silicon carbide semiconductor device according to an embodiment.

FIG. 2 is a flowchart schematically showing a method of manufacturing the silicon carbide semiconductor device according to the embodiment.

FIG. 3 is a schematic diagram illustrating steps (S11) and (S12) in the method of manufacturing the silicon carbide semiconductor device according to the embodiment.

FIG. 4 is a schematic diagram illustrating steps (S13) and (S14) in the method of manufacturing the silicon carbide semiconductor device according to the embodiment.

FIG. 5 is a schematic diagram illustrating steps (S20) to (S40) in the method of manufacturing the silicon carbide semiconductor device according to the embodiment.

FIG. 6 is a graph showing relation between time and heating temperature in the steps (S20) to (S40) of the method of manufacturing the silicon carbide semiconductor device according to the embodiment.

FIG. 7 is a schematic diagram illustrating a step (S50) in the method of manufacturing the silicon carbide semiconductor device according to the embodiment.

FIG. 8 is a schematic diagram illustrating a step (S60) in the method of manufacturing the silicon carbide semiconductor device according to the embodiment.

FIG. 9 is a graph showing nitrogen concentration distribution along a thickness direction of a SiC-MOSFET.

### DESCRIPTION OF EMBODIMENTS

### Description of Embodiment of the Present Invention

First, the contents of an embodiment of the present invention will be listed and described.

(1) A silicon carbide semiconductor device according to this embodiment includes a silicon carbide substrate, a gate insulating film formed on a surface of the silicon carbide substrate and made of silicon oxide, and a gate electrode formed on the gate insulating film. A maximum value of a nitrogen concentration in a region within 10 nm from an interface between the silicon carbide substrate and the gate insulating film is greater than or equal to 3×10¹⁹ cm⁻³. A maximum value of a nitrogen concentration in a region within 10 nm from an interface between the gate insulating film and the gate electrode is less than or equal to 1×10²⁰ cm⁻³.

Diligent studies were conducted by the present inventor to improve the channel mobility and increase the threshold voltage of a silicon carbide semiconductor device. As a result, the present invention was conceived based on the findings that both the channel mobility and the threshold voltage can be increased by controlling a nitrogen concentration in each of an interface between a silicon carbide substrate and a gate insulating film and an interface between the gate insulating film and a gate electrode. According to the studies by the present inventor, the channel mobility of a silicon carbide semiconductor device is improved by introducing nitrogen atoms such that a maximum value of a nitrogen concentration in a region within 10 nm from an interface between a silicon carbide substrate and a gate insulating film is greater than or equal to 3×10¹⁹ cm⁻³. Meanwhile, the threshold voltage of a silicon carbide semiconductor device can be increased by setting a maximum value of a nitrogen concentration in a region within 10 nm from an interface between the gate insulating film and a gate electrode to less than or equal to 1×10²⁰ cm⁻³.

In the silicon carbide semiconductor device described above, the maximum value of the nitrogen concentration in the region within 10 nm from the interface between the silicon carbide substrate and the gate insulating film is greater than or equal to 3×10¹⁹ cm⁻³, and the maximum value of the nitrogen concentration in the region within 10 nm from the interface between the gate insulating film and the gate electrode is less than or equal to 1×10²⁰ cm⁻³. According to the silicon carbide semiconductor device described above, therefore, a silicon carbide semiconductor device having improved channel mobility as well as a high threshold voltage can be provided. It is noted that the maximum values of the nitrogen concentrations in the regions within 10 nm from the aforementioned interfaces can be measured as described in a specific example of this embodiment to be described below.

(2) In the silicon carbide semiconductor device described above, a region where the nitrogen concentration is greater than or equal to 1×10¹⁹ cm⁻³ may account for greater than or equal to 80% of the gate insulating film in a thickness direction.

Thereby, the nitrogen atoms can be distributed more uniformly within the gate insulating film. As a result, the threshold voltage of the silicon carbide semiconductor device can be further increased.

(3) In the silicon carbide semiconductor device described above, the gate electrode may include polysilicon.

If the gate electrode includes polysilicon, the polysilicon reacts with the silicon oxide constituting the gate insulating film, with the result that the nitrogen concentration tends to increase at the interface between the gate insulating film and the gate electrode. If the gate electrode includes polysilicon, therefore, the silicon carbide semiconductor device described above in which the nitrogen concentration in the interface between the gate insulating film and the gate electrode is suppressed can be suitably used.

(4) In the silicon carbide semiconductor device described above, the maximum value of the nitrogen concentration in the region within 10 nm from the interface between the silicon carbide substrate and the gate insulating film may be less than or equal to 1×10²¹ cm⁻³.

If the maximum value of the nitrogen concentration exceeds 1×10²¹ cm⁻³, the channel mobility is significantly improved, whereas the threshold voltage decreases. By setting the maximum value of the nitrogen concentration to less than or equal to 1×10²¹ cm⁻³, therefore, both the channel mobility and the threshold voltage can be increased.

(5) In the silicon carbide semiconductor device described above, the maximum value of the nitrogen concentration in the region within 10 nm from the interface between the gate insulating film and the gate electrode may be less than or equal to 3×10¹⁹ cm⁻³. Thereby, the threshold voltage of the silicon carbide semiconductor device can be further increased.

(6) In the silicon carbide semiconductor device described above, the surface of the silicon carbide substrate may have an off angle of less than or equal to 8° relative to a (0001) plane. Thereby, the improvement in channel mobility by controlling the nitrogen concentration in the interface between the silicon carbide substrate and the gate insulating film becomes more pronounced.

(7) A method of manufacturing a silicon carbide semiconductor device according to this embodiment includes the steps of preparing a silicon carbide substrate, forming a gate insulating film made of silicon oxide on a surface of the silicon carbide substrate, heating the silicon carbide substrate having the gate insulating film formed thereon at a temperature greater than or equal to 1100° C. in an atmosphere including nitrogen, and after the step of heating the silicon carbide substrate, forming a gate electrode on the gate insulating film. In the method of manufacturing a silicon carbide semiconductor device described above, after the step of forming a gate electrode, the silicon carbide substrate is not heated at a temperature greater than or equal to 900° C. in an atmosphere including greater than or equal to 10% nitrogen.

Diligent studies were conducted by the present inventor to find a method of manufacturing a silicon carbide semiconductor device having improved channel mobility as well as a high threshold voltage. As a result, the present invention was conceived based on the following findings.

First, by heating a silicon carbide substrate having a gate insulating film formed thereon at a temperature greater than or equal to a prescribed temperature in an atmosphere including nitrogen, a nitrogen concentration sufficient for improving the channel mobility in an interface between the silicon carbide substrate and the gate insulating film can be secured. Further, after a gate electrode is formed on the gate insulating film, if the silicon carbide substrate is heated at a temperature greater than or equal to a prescribed temperature in an atmosphere including nitrogen at a concentration greater than or equal to a prescribed concentration, the nitrogen concentration in an interface between the gate insulating film and the gate electrode becomes excessive, resulting in a reduction in threshold voltage of the silicon carbide semiconductor device.

In the method of manufacturing a silicon carbide semiconductor device described above, the silicon carbide substrate having the gate insulating film formed thereon is heated at a temperature greater than or equal to 1100° C. in an atmosphere including nitrogen. Thereby, a sufficient nitrogen concentration is secured at the interface between the silicon carbide substrate and the gate insulating film, thereby improving the channel mobility of the silicon carbide semiconductor device. Further, the method of manufacturing a silicon carbide semiconductor device described above is performed in such a manner that, after the gate electrode is formed on the gate insulating film, the silicon carbide substrate is not heated at a temperature greater than or equal to 900° C. in an atmosphere including greater than or equal to 10% nitrogen. Thereby, an increase in nitrogen concentration in the interface between the gate insulating film and the gate electrode is suppressed, thereby suppressing the reduction in threshold voltage. According to the method of manufacturing a silicon carbide semiconductor device described above, therefore, a silicon carbide semiconductor device having improved channel mobility as well as a high threshold voltage can be manufactured.

The “atmosphere including nitrogen” as used herein refers to an atmosphere including gas containing nitrogen atoms, for example, an atmosphere including gas such as nitrogen monoxide (NO), nitrous oxide (N₂O), nitrogen (N₂) or ammonia (NH₃). The gas containing nitrogen atoms refers to gas that can contribute to the introduction of nitrogen atoms into the aforementioned interfaces. The “atmosphere including greater than or equal to 10% nitrogen” refers to an atmosphere in which a ratio (volume ratio or flow ratio) of the gas containing nitrogen atoms such as nitrogen monoxide (NO), nitrous oxide (N₂O), nitrogen (N₂) and ammonia (NH₃) is greater than or equal to 10% of the total.

(8) The method of manufacturing a silicon carbide semiconductor device described above may further include the step of, after the step of heating the silicon carbide substrate and before the step of forming a gate electrode, heating the silicon carbide substrate at a temperature greater than or equal to 1100° C. in an atmosphere including inert gas. Argon (Ar), helium (He) or nitrogen (N₂), for example, can be used as the inert gas.

Thereby, the nitrogen atoms can be distributed more uniformly within the gate insulating film. As a result, the threshold voltage of the silicon carbide semiconductor device can be further increased.

(9) The method of manufacturing a silicon carbide semiconductor device described above may further include the step of, after the step of forming a gate electrode, forming a source electrode on the silicon carbide substrate. In the step of forming a source electrode, the substrate may be heated at a temperature greater than or equal to 900° C. in an atmosphere including less than 10% nitrogen. Thereby, the source electrode can be formed while an increase in nitrogen concentration in the interface between the gate insulating film and the gate electrode is suppressed. It is noted that the “atmosphere including less than 10% nitrogen” is defined in a similar manner to the “atmosphere including greater than or equal to 10% nitrogen” described above.

(10) In the method of manufacturing a silicon carbide semiconductor device described above, after the step of forming a gate electrode, the silicon carbide substrate may not be heated at a temperature greater than or equal to 1100° C. in an atmosphere including greater than or equal to 10% nitrogen. Thereby, an increase in nitrogen concentration in the interface between the gate insulating film and the gate electrode can be more reliably suppressed.

(11) In the method of manufacturing a silicon carbide semiconductor device described above, in the step of heating the silicon carbide substrate, the silicon carbide substrate may be heated in an atmosphere including at least one gas selected from the group consisting of nitrogen monoxide (NO), nitrous oxide (N₂O), nitrogen (N₂) and ammonia (NH₃). By using the aforementioned gas containing nitrogen atoms (NO, N₂O, N₂, NH₃), the introduction of the nitrogen atoms into the interface between the silicon carbide substrate and the gate insulating film to secure a sufficient nitrogen concentration in this interface is facilitated.

### Details of Embodiment of the Present Invention

Next, a specific example of the embodiment of the present invention will be described with reference to the drawings. In the following drawings, the same or corresponding parts are designated by the same reference numbers and description thereof will not be repeated. An individual orientation, a group orientation, an individual plane, and a group plane are herein shown in [ ], < >, ( ) and { }, respectively. Although a crystallographically negative index is normally expressed by a number with a bar “-” thereabove, a negative sign herein precedes a number to indicate a crystallographically negative index.

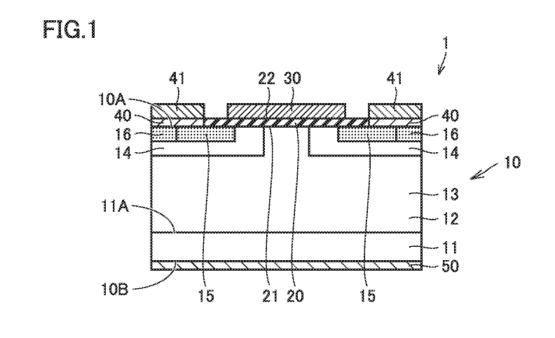

First, a structure of a silicon carbide semiconductor device according to the embodiment of the present invention is described. Referring to FIG. 1, a silicon carbide (SiC) semiconductor device 1 according to this embodiment is a vertical Di (Double Implanted) MOSFET, and mainly includes a silicon carbide (SiC) substrate 10, a gate insulating film 20, a gate electrode 30, a source electrode 40, a drain electrode 50, and an upper source electrode 41.

A surface 10A of SiC substrate 10 has an off angle of less than or equal to 8° relative to a (0001) plane, and preferably has an off angle of less than or equal to 4°. It is noted that surface 10A of SiC substrate 10 is not thus limited, but may be a (0-33-8) plane, for example.

SiC substrate 10 mainly includes a base substrate 11, and a silicon carbide (SiC) layer 12 formed by epitaxial growth on a surface 11A of base substrate 11. SiC layer 12 mainly has a drift region 13, a body region 14, a source region 15, and a contact region 16.

Drift region 13 is formed on one surface 11A of base substrate 11. Drift region 13 has n type conductivity by including an n type impurity such as nitrogen (N). Body regions 14 are formed at a distance from each other in SiC layer 12. Body region 14 has p type conductivity by including a p type impurity such as aluminum (Al) or boron (B).

Source region 15 is formed in body region 14 so as to include surface 10A. Source region 15 has n type conductivity by including an n type impurity such as phosphorus (P). Source region 15 is higher in n type impurity concentration than drift region 13.

Contact region 16 is formed in body region 14 so as to include surface 10A and be adjacent to source region 15. Contact region 16 has p type conductivity by including a p type impurity such as aluminum (Al). Contact region 16 is higher in p type impurity concentration than body region 14.

Gate insulating film 20 is formed on and in contact with surface 10A of SiC substrate 10. Gate insulating film 20 is made of silicon oxide such as silicon dioxide (SiO₂), and is formed to extend from above one of source regions 15 to above the other source region 15.

Gate electrode 30 is formed on and in contact with gate insulating film 20 (opposite side to the SiC substrate 10 side). Gate electrode 30 is made of a conductor such as polysilicon doped with an impurity or aluminum (Al), and is formed to extend from above one of source regions 15 to above the other source region 15.

Source electrode 40 is formed on and in contact with surface 10A of SiC substrate 10 (over source region 15 and contact region 16). Source electrode 40 is made of a material capable of making ohmic contact with source region 15, for example, NiₓSi_{y} (nickel silicide), TiₓSi_{y} (titanium silicide), AlₓSi_{y} (aluminum silicide) and TiₓAl_{y}Si_{z} (titanium aluminum silicide) (x, y, z>0).

Drain electrode 50 is formed on a surface 10B opposite to surface 10A of SiC substrate 10. Drain electrode 50 is made of a material similar to that for source electrode 40, and is in ohmic contact with SiC substrate 10.

In a region including an interface 21 between SiC substrate 10 and gate insulating film 20, a maximum value of a nitrogen concentration is greater than or equal to 3×10¹⁹ cm⁻³ and less than or equal to 1×10²¹ cm⁻³, and preferably greater than or equal to 1×10²⁰ cm⁻³ and less than or equal to 5×10²⁰ cm⁻³. More specifically, a maximum value of a nitrogen concentration is within this range in a region including interface 21 between drift region 13 and gate insulating film 20, a region including interface 21 between body region 14 and gate insulating film 20, and a region including interface 21 between source region 15 and gate insulating film 20. The region including interface 21 as used herein refers to a region within 10 nm in a thickness direction of SiC substrate 10 when viewed from interface 21. In a region including an interface 22 between gate insulating film 20 and gate electrode 30, a maximum value of a nitrogen concentration is less than or equal to 1×10²⁰ cm⁻³, preferably less than or equal to 3×10¹⁹ cm⁻³, and more preferably less than or equal to 1×10¹⁹ cm⁻³. The region including interface 22 as used herein refers to a region within 10 nm in the thickness direction of SiC substrate 10 when viewed from interface 22.

The nitrogen concentration in the region within 10 nm from interface 21 between SiC substrate 10 and gate insulating film 20, and the nitrogen concentration in the region within 10 nm from interface 22 between gate insulating film 20 and gate electrode 30 can be measured using SIMS (Secondary Ion Mass Spectrometry). More specifically, nitrogen concentration distribution along the thickness direction of SiC semiconductor device 1 is obtained by the SIMS measurement, and the maximum values of the nitrogen concentrations in the regions within 10 nm from interfaces 21 and 22 can be determined by this nitrogen concentration distribution.

Next, operation of SiC semiconductor device 1 according to this embodiment is described. Referring to FIG. 1, when a voltage applied to gate electrode 30 is less than a threshold voltage, namely, in an OFF state, even if a voltage is applied between source electrode 40 and drain electrode 50, a pn junction formed between body region 14 and drift region 13 is reverse biased, resulting in a non-conducting state. When a voltage greater than or equal to the threshold voltage is applied to gate electrode 30, on the other hand, an inversion layer is formed in a channel region of body region 14 (body region 14 below gate electrode 30). As a result, source region 15 and drift region 13 are electrically connected together, causing a current to flow between source electrode 40 and drain electrode 50. This causes operation of SiC semiconductor device 1.

As described above, in SiC semiconductor device 1 according to this embodiment, the maximum value of the nitrogen concentration in the region within 10 nm from interface 21 between SiC substrate 10 and gate insulating film 20 is greater than or equal to 3×10¹⁹ cm⁻³, and the maximum value of the nitrogen concentration in the region within 10 nm from interface 22 between gate insulating film 20 and gate electrode 30 is less than or equal to 1×10²⁰ cm⁻³. Thereby, SiC semiconductor device 1 has improved channel mobility as well as a high threshold voltage.

In SiC semiconductor device 1 described above, a region where the nitrogen concentration is greater than or equal to 1×10¹⁹ cm⁻³ may account for greater than or equal to 80% of gate insulating film 20 in the thickness direction, and the region where the nitrogen concentration is greater than or equal to 1×10¹⁹ cm⁻³ may account for the whole of gate insulating film 20 in the thickness direction. Thereby, the nitrogen atoms can be distributed more uniformly within gate insulating film 20. As a result, the threshold voltage of SiC semiconductor device 1 can be further increased. It is noted that the nitrogen concentration distribution along the thickness direction of gate insulating film 20 can be obtained by the SIMS measurement in a manner similar to above.

In SiC semiconductor device 1 described above, gate electrode 30 may include polysilicon as mentioned above. The polysilicon constituting gate electrode 30 reacts with SiO₂ constituting gate insulating film 20, thereby facilitating the introduction of nitrogen atoms into interface 22 between gate insulating film 20 and gate electrode 30. If gate electrode 30 includes polysilicon, therefore, SiC semiconductor device 1 described above capable of suppressing the nitrogen concentration in a portion near interface 22 between gate insulating film 20 and gate electrode 30 is suitable.

In SiC semiconductor device 1 described above, surface 10A of SiC substrate 10 may have an off angle of less than or equal to 8° relative to the (0001) plane as mentioned above. If surface 10A of SiC substrate 10 is on a silicon face ((0001) plane), the improvement in channel mobility by the introduction of nitrogen atoms into a portion near interface 21 between SiC substrate 10 and gate insulating film 20 becomes more pronounced than when surface 10A is on a carbon face ((000-1) plane).

Next, a method of manufacturing the SiC semiconductor device according to this embodiment is described. In the method of manufacturing the SiC semiconductor device according to this embodiment, SiC semiconductor device 1 according to this embodiment described above can be manufactured (see FIG. 1).

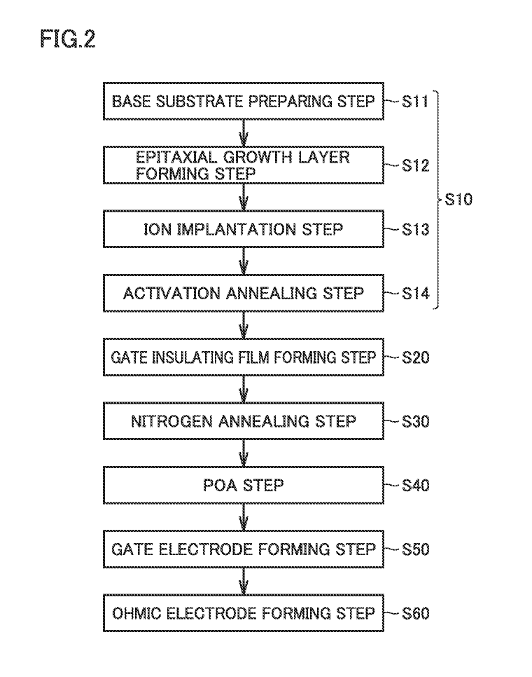

Referring to FIG. 2, in the method of manufacturing the SiC semiconductor device according to this embodiment, first, a SiC substrate preparing step is performed as a step (S10). In this step (S10), SiC substrate 10 is prepared by performing steps (S11) to (S14) described below.

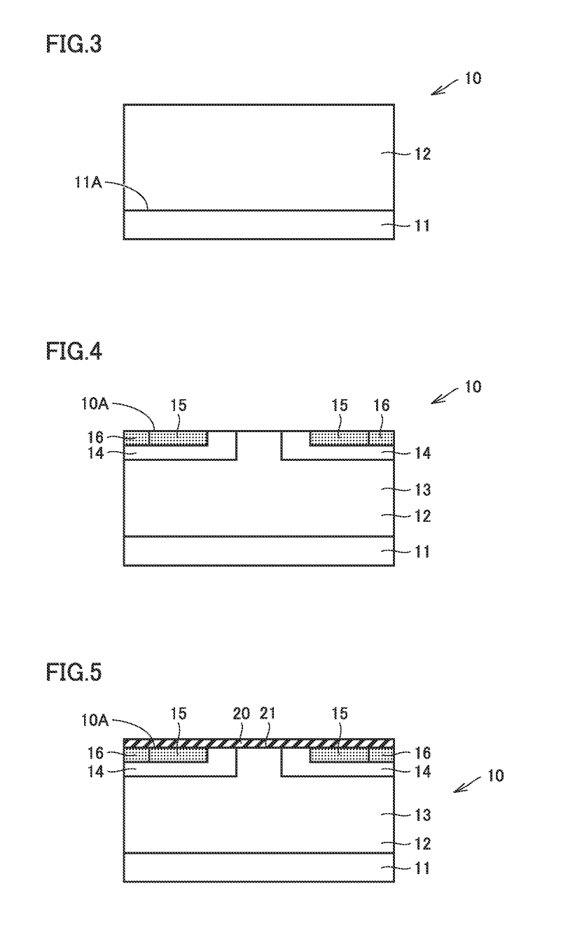

First, a base substrate preparing step is performed as a step (S11). In this step (S11), referring to FIG. 3, base substrate 11 is prepared by cutting an ingot made of 4H-SiC (not shown), for example.

Next, an epitaxial growth layer forming step is performed as a step (S12). In this step (S12), referring to FIG. 3, SiC layer 12 is formed by epitaxial growth on surface 11A of base substrate 11.

Next, an ion implantation step is performed as a step (S13). In this step (S13), referring to FIG. 4, first, aluminum (Al) ions, for example, are implanted into SiC layer 12 to form body region 14 in SiC layer 12. Then, phosphorus (P) ions, for example, are implanted into body region 14 to form source region 15 in body region 14. Then, aluminum (Al) ions, for example, are implanted into body region 14 to form contact region 16 adjacent to source region 15 in body region 14. Then, a region in SiC layer 12 where none of body region 14, source region 15 and contact region 16 is formed serves as drift region 13.

Next, an activation annealing step is performed as a step (S14). In this step (S14), referring to FIG. 4, SiC layer 12 is heated to activate the impurities introduced in the step (S13). Thereby, desired carriers are generated in the impurity regions. SiC substrate 10 is prepared by performing the steps (S11) to (S14) in this manner.

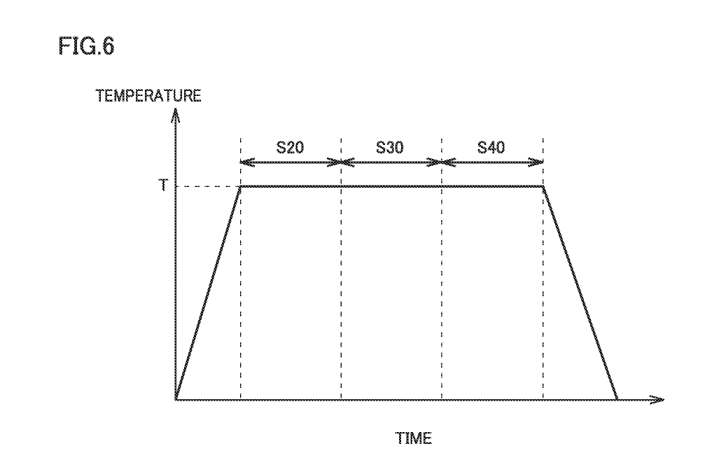

Next, steps (S20) to (S40) are described with reference to FIGS. 5 and 6. FIG. 6 is a graph showing temporal variation in heating temperature of SiC substrate 10 in the steps (S20) to (S40) (horizontal axis: time, vertical axis: heating temperature).

First, a gate insulating film forming step is performed as a step (S20). In this step (S20), referring to FIGS. 5 and 6, gate insulating film 20 made of SiO₂ is formed on surface 10A by heating SiC substrate 10 at a temperature T in an atmosphere including oxygen, for example.

Next, a nitrogen annealing step is performed as a step (S30). In this step (S30), referring to FIG. 5, SiC substrate 10 having gate insulating film 20 formed thereon is heated at a temperature greater than or equal to 1100° C. (preferably greater than or equal to 1300° C. and less than or equal to 1400° C.) (temperature T in FIG. 6) in an atmosphere including at least one gas selected from the group consisting of nitrogen monoxide (NO), nitrous oxide (N₂O), nitrogen (N₂) and ammonia (NH₃). Thereby, nitrogen atoms are introduced into a region including interface 21 between SiC substrate 10 and gate insulating film 20.

Next, a POA (Post Oxidation Annealing) step is performed as a step (S40). In this step (S40), SiC substrate 10 is heated at a temperature greater than or equal to 1100° C. (preferably greater than or equal to 1300° C. and less than or equal to 1400° C.) (temperature T in FIG. 6) in an atmosphere including inert gas such as argon (Ar), nitrogen (N₂) or helium (He). Thereby, the nitrogen atoms introduced into interface 21 in the step (S30) are diffused uniformly within gate insulating film 20. While the heating temperature of SiC substrate 10 may be constant throughout the steps (S20) to (S40) as shown in FIG. 6, the temperature may vary as appropriate among the steps.

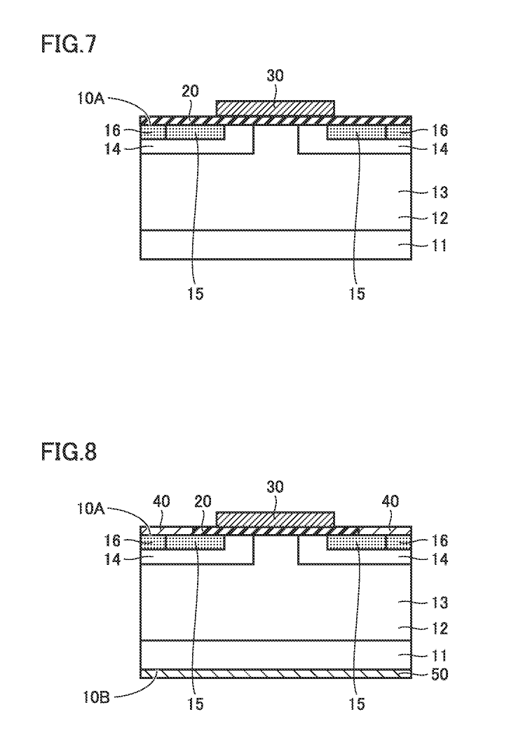

Next, a gate electrode forming step is performed as a step (S50). In this step (S50), referring to FIG. 7, gate electrode 30 made of polysilicon is formed on and in contact with gate insulating film 20 by LPCVD (Low Pressure Chemical Vapor Deposition), for example.

Next, an ohmic electrode forming step is performed as a step (S60). In this step (S60), referring to FIG. 8, first, gate insulating film 20 is removed from a region where source electrode 40 is to be formed, to form a region where source region 15 and contact region 16 are exposed. Then, a film made of nickel (Ni), for example, is formed in this region. Meanwhile, a film made of Ni, for example, is formed on surface 10B of SiC substrate 10. Then, SiC substrate 10 is heated at a temperature greater than or equal to 900° C., to silicidize at least a portion of the film made of Ni. Here, during this heating, SiC substrate 10 is exposed to an atmosphere including less than 10% nitrogen. In this manner, source electrode 40 and drain electrode 50 are formed on surfaces 10A and 10B of SiC substrate 10, respectively.

SiC semiconductor device 1 described above (see FIG. 1) is manufactured by performing the steps (S10) to (S60), to complete the method of manufacturing the SiC semiconductor device according to this embodiment.

In the method of manufacturing the SiC semiconductor device according to this embodiment, after the gate electrode forming step (S50) is performed, SiC substrate 10 is not heated at a temperature greater than or equal to 900° C. (preferably greater than or equal to 1100° C.) in an atmosphere including greater than or equal to 10% nitrogen.

As described above, in the method of manufacturing the SiC semiconductor device according to this embodiment, after gate insulating film 20 is formed on surface 10A of SiC substrate 10 in the step (S20), SiC substrate 10 is heated at a temperature greater than or equal to 1100° C. in an atmosphere including nitrogen in the step (S30). Thereby, sufficient nitrogen atoms are introduced into the region including interface 21 between SiC substrate 10 and gate insulating film 20, thereby improving the channel mobility of SiC semiconductor device 1. Further, in the method of manufacturing the SiC semiconductor device described above, after gate electrode 30 is formed on gate insulating film 20 in the step (S50), SiC substrate 10 is not heated at a temperature greater than or equal to 900° C. in an atmosphere including greater than or equal to 10% nitrogen. Thereby, excessive introduction of nitrogen atoms into interface 22 between gate insulating film 20 and gate electrode 30 which results in a reduction in threshold voltage of SiC semiconductor device 1 can be suppressed. According to the method of manufacturing the SiC semiconductor device in accordance with this embodiment, therefore, SiC semiconductor device 1 according to this embodiment described above having improved channel mobility as well as a high threshold voltage can be manufactured.

The method of manufacturing the SiC semiconductor device described above may include, as described above, after the nitrogen annealing step (S30) and before the gate electrode forming step (S50), the step (S40) of heating SiC substrate 10 at a temperature greater than or equal to 1100° C. in an atmosphere including inert gas. While this step (S40) is not a required step, the nitrogen atoms can be distributed more uniformly within gate insulating film 20 by performing this step. As a result, the threshold voltage of SiC semiconductor device 1 can be further increased.

The method of manufacturing the SiC semiconductor device described above may include, after the gate electrode forming step (S50), the step (S60) of forming source electrode 40 on SiC substrate 10. In the step (S60), SiC substrate 10 may be heated at a temperature greater than or equal to 900° C. in an atmosphere having a nitrogen concentration of less than 10%. Thereby, excessive introduction of nitrogen atoms into interface 22 between gate insulating film 20 and gate electrode 30 during alloying can be suppressed. As a result, a reduction in threshold voltage of SiC semiconductor device 1 can be more reliably suppressed.

While SiC semiconductor device 1 which is a planar MOSFET and the method of manufacturing the same have been discussed in this embodiment described above, this is not limiting. For example, as another embodiment, a trench MOSFET having a sidewall surface formed of a (0-33-8) plane and a method of manufacturing the same are also possible.

### Example

Experiments were conducted to confirm the effect with regard to improvement in channel mobility and threshold voltage.

(Fabrication of SiC-MOSFETs)

First, as an example, a SiC-MOSFET was fabricated with the method of manufacturing the SiC semiconductor device of this embodiment described above (No. 1). Further, as a comparative example, a SiC-MOSFET was fabricated by performing the steps (S10) to (S50) in a manner similar to the above example, and heating the SiC substrate at a temperature greater than or equal to 900° C. in an atmosphere including greater than or equal to 10% nitrogen after the step (S50) (No. 2). Further, as another comparative example, a SiC-MOSFET was fabricated without performing the nitrogen annealing step (S30) in the above example (No. 3). Further, as yet another comparative example, a SiC-MOSFET was fabricated without performing the nitrogen annealing step (S30) and by heating the SiC substrate at a temperature greater than or equal to 900° C. in an atmosphere including greater than or equal to 10% nitrogen after the step (S50) in the above example (No. 4).

(Measurement of Nitrogen Concentration Distributions)

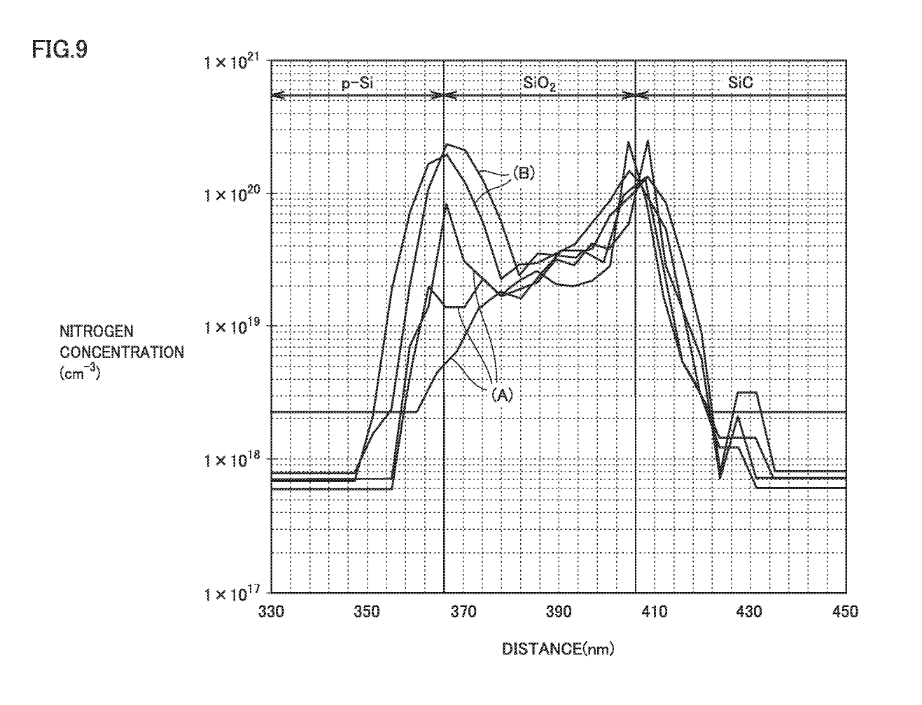

A SIMS measurement was conducted on the SiC-MOSFETs of the above example and comparative examples, and nitrogen concentration distributions shown in FIG. 9 were obtained. In FIG. 9, a horizontal axis represents a distance (nm) in a thickness direction of the SiC-MOSFET, and a vertical axis represents a nitrogen concentration (cm⁻³). An area indicated with “p-Si” in FIG. 9 corresponds to the gate electrode, an area indicated with “SiO₂” corresponds to the gate insulating film, and an area indicated with “SiC” corresponds to the SiC substrate. In addition, (A) in FIG. 9 indicates nitrogen concentration distributions in No. 1 of the example, and (B) indicates nitrogen concentration distributions in No. 2 of the comparative example. From these nitrogen concentration distributions, a maximum value of the nitrogen concentration in each region within 10 nm from the interface between the SiC substrate and the gate insulating film and the interface between the gate insulating film and the gate electrode was determined.

(Measurement of Channel Mobility and Threshold Voltage)

The channel mobility and threshold voltage of the SiC-MOSFETs of the above example and comparative examples were measured. The results of the above experiments are shown in Table 1.

TABLE 1

| | Channel Mobility | Threshold Voltage |
|---|---|---|
| | (cm²/Vs) | (V) |
| No. 1 | 15-20 | 1.5 |
| No. 2 | 15-20 | 1 |
| No. 3 | 5-8 | 2-3 |
| No. 4 | 5-8 | 1-1.8 |

(Experimental Results)

Referring to FIG. 9, in No. 1 of the example ((A) in FIG. 9), the maximum value of the nitrogen concentration in the region within 10 nm from the interface between the SiC substrate and the gate insulating film was greater than or equal to 3×10¹⁹ cm⁻³ (greater than or equal to 1×10²⁰ cm⁻³), and the maximum value of the nitrogen concentration in the region within 10 nm from the interface between the gate insulating film and the gate electrode was less than or equal to 1×10²⁰ cm⁻³. In No. 2 of the comparative example ((B) in FIG. 9), on the other hand, the maximum value of the nitrogen concentration in the region within 10 nm from the interface between the gate insulating film and the gate electrode exceeded 1×10²⁰ cm⁻³.

Referring to Table 1, in No. 1 of the example, the channel mobility (μ) was 15 to 20 cm²/Vs, and the threshold voltage was about 1.5 V. In No. 2 of the comparative example, on the other hand, while the channel mobility was 15 to 20 cm²/Vs, the threshold voltage decreased to as low as 1.0 V. In No. 3 of another comparative example, while the threshold voltage was as high as 2 to 3 V, the channel mobility decreased to as low as 5 to 8 cm²/Vs. In No. 4 of still another comparative example, the channel mobility decreased to as low as 5 to 8 cm²/Vs, and the threshold voltage was also 1 to 1.8 V. It was found from these experimental results that both the channel mobility and the threshold voltage could be increased by setting the maximum value of the nitrogen concentration in the region within 10 nm from the interface between the SiC substrate and the gate insulating film to greater than or equal to 3×10¹⁹ cm⁻³, and setting the maximum value of the nitrogen concentration in the region within 10 nm from the interface between the gate insulating film and the gate electrode to less than or equal to 1×10²⁰ cm⁻³.

It should be understood that the embodiments and examples disclosed herein are illustrative and non-restrictive in every respect. The scope of the present invention is defined by the terms of the claims, rather than the description above, and is intended to include any modifications within the scope and meaning equivalent to the terms of the claims.

### INDUSTRIAL APPLICABILITY

The silicon carbide semiconductor device and the method of manufacturing the same of the present application can be applied particularly advantageously to a silicon carbide semiconductor device required to have improved channel mobility as well as an increased threshold voltage and a method of manufacturing the same.

### REFERENCE SIGNS LIST

1 silicon carbide (SiC) semiconductor device; 10 silicon carbide (SiC) substrate; 10A, 10B, 11A surface; 11 base substrate; 12 silicon carbide (SiC) layer; 13 drift region; 14 body region; 15 source region; 16 contact region; 20 gate insulating film; 21, 22 interface; 30 gate electrode; 40 source electrode; 41 upper source electrode; 50 drain electrode.

1. A silicon carbide semiconductor device comprising:
a silicon carbide substrate;
a gate insulating film formed on a surface of the silicon carbide substrate and made of silicon oxide; and
a gate electrode formed on the gate insulating film, a maximum value of a nitrogen concentration in a region within 10 nm from an interface between the silicon carbide substrate and the gate insulating film being greater than or equal to 3×10¹⁹ cm⁻³, and
a maximum value of a nitrogen concentration in a region within 10 nm from an interface between the gate insulating film and the gate electrode being less than or equal to 1×10²⁰ cm⁻³.

2. The silicon carbide semiconductor device according to claim 1, wherein a region where the nitrogen concentration is greater than or equal to 1×10¹⁹ cm⁻³ accounts for greater than or equal to 80% of the gate insulating film in a thickness direction.

3. The silicon carbide semiconductor device according to claim 1, wherein
the gate electrode includes polysilicon.

4. The silicon carbide semiconductor device according to claim 1, wherein
the maximum value of the nitrogen concentration in the region within 10 nm from the interface between the silicon carbide substrate and the gate insulating film is less than or equal to 1×10²¹ cm⁻³.

5. The silicon carbide semiconductor device according to claim 1, wherein
the maximum value of the nitrogen concentration in the region within 10 nm from the interface between the gate insulating film and the gate electrode is less than or equal to 3×10¹⁹ cm⁻³.

6. The silicon carbide semiconductor device according to claim 1, wherein
the surface of the silicon carbide substrate has an off angle of less than or equal to 8° relative to a (0001) plane.

7. A method of manufacturing a silicon carbide semiconductor device, comprising the steps of:
preparing a silicon carbide substrate;
forming a gate insulating film made of silicon oxide on a surface of the silicon carbide substrate;
heating the silicon carbide substrate having the gate insulating film formed thereon at a temperature greater than or equal to 1100° C. in an atmosphere including nitrogen; and
after the step of heating the silicon carbide substrate, forming a gate electrode on the gate insulating film,
after the step of forming a gate electrode, the silicon carbide substrate not being heated at a temperature greater than or equal to 900° C. in an atmosphere including greater than or equal to 10% nitrogen.

8. The method of manufacturing a silicon carbide semiconductor device according to claim 7, further comprising the step of, after the step of heating the silicon carbide substrate and before the step of forming a gate electrode, heating the silicon carbide substrate at a temperature greater than or equal to 1100° C. in an atmosphere including inert gas.

9. The method of manufacturing a silicon carbide semiconductor device according to claim 7, further comprising the step of, after the step of forming a gate electrode, forming a source electrode on the silicon carbide substrate, wherein
in the step of forming a source electrode, the silicon carbide substrate is heated at a temperature greater than or equal to 900° C. in an atmosphere including less than 10% nitrogen.

10. The method of manufacturing a silicon carbide semiconductor device according to claim 7, wherein
after the step of forming a gate electrode, the silicon carbide substrate is not heated at a temperature greater than or equal to 1100° C. in an atmosphere including greater than or equal to 10% nitrogen.

11. The method of manufacturing a silicon carbide semiconductor device according to claim 7, wherein
in the step of heating the silicon carbide substrate, the silicon carbide substrate is heated in an atmosphere including at least one gas selected from the group consisting of nitrogen monoxide, nitrous oxide, nitrogen and ammonia.
